(19) United States
(12) Patent Application Publication
(10) Pub. No.: US 2009/0027882 A1
(43) Pub. Date: Jan. 29, 2009

(54) Backlight Assembly, Method of Manufacturing the Same and Display Device Having the Same

(75) Inventors: Gi-Cherl Kim, Gyeonggi-do (KR); Don-Chan Cho, Gyeonggi-do (KR); Young-Keun Lee, Chungcheongnam-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co.,Ltd.

(21) Appl. No.: 11/782,152

(22) Filed: Jul. 24, 2007

(30) Foreign Application Priority Data
Jul. 24, 2007 (KR) 2006-69163

(51) Int. Cl. F21S 2/00; F21V 33/00; H01L 21/77

(52) U.S. Cl. 362/234; 362/227; 438/34; 257/E21.532

(57) ABSTRACT

A backlight assembly includes a light-generating unit and a receiving container. The light-generating unit includes at least one point light source generating light and a power supply line transferring power for driving the point light source. The receiving container receives the light-generating unit, and the power supply line is formed on an insulating layer included in the receiving container.

### CROSS-REFERENCE TO RELATED APPLICATIONS

This application relies for priority upon Korean Patent Application No. 10-2006-0069163 filed on Jul. 24, 2006, the contents of which are herein incorporated by reference in their entireties.

### BACKGROUND OF THE INVENTION

1. Field of the Invention

The present invention relates to a backlight assembly, a method of manufacturing the backlight assembly, and a display device having the backlight assembly. More particularly, the present invention relates to a backlight assembly providing reduced manufacturing cost and enhanced cooling efficiency, a method of manufacturing the backlight assembly and a display device having the backlight assembly.

2. Description of the Related Art

Generally, a liquid crystal display (LCD) device as one of a flat panel display device displays an image using electrical and optical characteristics of liquid crystal.

The LCD device includes a liquid crystal control unit that controls liquid a crystal material and a light-providing unit that provides light to the liquid crystal. For example, the LCD device includes an LCD panel serving as the liquid crystal control unit, and a backlight assembly serving as the light-providing unit.

The backlight assembly includes a light source generating light. Examples of the light source include a cold cathode fluorescent lamp (CCFL) having a cylindrical shape and a light emitting diode (LED) having a dot shape.

A backlight assembly of a direct illumination type LCD, which employs an LED as a light source, includes a printed circuit board (PCB) for driving the LED in a receiving space of a receiving container. The PCB is disposed on a bottom plate of the receiving container, and the LED is mounted on the PCB.

When the LED is energized, the LED generates significant heat and the heat is transferred to the receiving container through the PCB. Thus, the PCB includes a material having sufficient heat transfer characteristics. Examples of the PCB includes a metal core PCB (MCPCB) consisting of a metal layer and FR-4 PCB laminate base material.

The MCPCB and the FR-4 PCB is relatively expensive, and occupies a large portion of the bottom plate of the receiving container. Thus, the manufacturing cost of the direct illumination type backlight assembly is increased.

Also, although the PCB includes a material having sufficient heat discharge characteristics, external transfer of the heat generated from the LED through the PCB results in reduced cooling efficiency.

### SUMMARY OF THE INVENTION

The present invention provides a backlight assembly with reduced manufacturing cost and enhanced cooling efficiency.

The present invention also provides a method of manufacturing the above-mentioned backlight assembly.

The present invention also provides a display device utilizing the above-mentioned backlight assembly.

In one aspect of the present invention, a backlight assembly includes a light-generating unit and a receiving container. The light-generating unit includes at least one point light source generating light and a power supply line transferring a power source for driving the point light source. The receiving container receives the light-generating unit, and the power supply line is formed on the receiving container.

In an exemplary embodiment, the receiving container includes a bottom plate and a sidewall protruding from an edge portion of the bottom plate to define a receiving space, and the power supply line is formed on the bottom plate.

The light-generating unit may include a plurality of point light sources, and an insulation layer may be formed between the bottom plate of the receiving container and the power supply line of the light-generating unit to electrically insulate the point light sources from each other.

The backlight assembly may further include a heat transfer member disposed between the point light source and the bottom plate of the receiving container to externally transfer heat generated from the point light source. The heat transfer member may also serve to fasten the point light source to the bottom plate of the receiving container.

A portion of the insulation layer corresponding to the point light source may be removed, and the heat transfer member may be formed at the removed portion. For example, the heat transfer member includes one of a thermally conductive adhesive and a solder material.

The heat transfer member may be integrally formed with the bottom plate of the receiving container, and the heat transfer member may protrude from the upper surface of the bottom plate. Here, the backlight assembly may further include an adhesive member disposed between the heat transfer member and the point light source to adhere the heat transfer member and the point light source to each other.

In an exemplary embodiment, the point light source includes a light emitting diode (LED) chip generating light, a first electrode and a second electrode that are electrically connected to the power supply line to apply a power source to the LED chip and an encapsulation layer covering and encapsulating the LED chip.

In another aspect of the present invention, a backlight assembly includes a light-generating unit and a receiving container. The light-generating unit includes at least one point light source generating light. The receiving container includes a bottom plate and a sidewall and receives the light-generating unit in a receiving space defined by the bottom plate and the sidewall. The point light source of the light-generating unit is formed on the bottom plate of the receiving container.

The light-generating unit may further include a power supply line transferring a power source for driving the point light source, and the power supply line may be formed on the bottom plate of the receiving container.

The light-generating unit may further include a plurality of point light sources, and an insulation layer may be formed between the bottom plate of the receiving container and the power supply line of the light-generating unit to electrically insulate the point light sources from each other.

Optionally, the backlight assembly further includes a heat transfer member disposed between the point light source and the bottom plate of the receiving container to fasten the point light source to the bottom plate of the receiving container and to externally transfer heat generated from the point light source.

In still another aspect of the present invention, a method of manufacturing a backlight assembly is provided as follows. A receiving container including a bottom plate and a sidewall and having a receiving space defined by the bottom plate and the sidewall is formed. An insulation layer is formed on the bottom plate of the receiving container. A conductive pattern is formed on the insulation layer. A point light source is formed on the bottom plate of the receiving container having the conductive pattern and is electrically connected to the conductive pattern.

The insulation layer may be formed by one of coating an insulating material and laminating an insulation foil, and the insulation layer may be formed on an entire portion of the bottom plate of the receiving container.

At least one of the insulation layer and the conductive pattern may be formed by a printing method. In an exemplary embodiment, the insulation layer may be formed by transporting the receiving container by using a first motor, transporting the printer head by using a second motor, a resolution of which is higher than that of the first motor, and ejecting an insulating material from the printer head. In an exemplary embodiment, the conductive pattern may be formed by transporting the receiving container by using a first motor, transporting the printer head by using a second motor, a resolution of which is higher than that of the first motor, and ejecting a conductive material from the printer head.

In still another aspect of the present invention, a display device includes a display unit and a backlight assembly. The display unit displays an image by using light. The backlight assembly provides the light to the display unit. The backlight assembly includes a light-generating unit and a receiving container. The light-generating unit includes at least one point light source generating light and a power supply line transferring a power source for driving the point light source. The receiving container receives the light-generating unit, and the power supply line is formed on the receiving container.

According to the above, a separate printed circuit board driving a point light source is omitted, and the point light source is mounted on a receiving container to be driven, thereby reducing manufacturing cost of a backlight assembly having the point light source.

### BRIEF DESCRIPTION OF THE DRAWINGS

The above and other features and advantage points of the present invention will become more apparent by describing in detailed exemplary embodiments thereof with reference to the accompanying drawings, in which:

FIG. 1 is an exploded perspective view illustrating a backlight assembly according to an exemplary embodiment of the present invention;

FIG. 2 is a partial cross-sectional view taken along a line I-I′ in FIG. 1;

FIG. 3 is a cross-sectional view illustrating a point light source of the backlight assembly illustrated in FIG. 1;

FIG. 4 is a plan view illustrating an exemplary embodiment of an insulation layer of the backlight assembly illustrated in FIG. 1;

FIG. 5 is a plan view illustrating another exemplary embodiment of an insulation layer of the backlight assembly illustrated in FIG. 1;

FIG. 6 is a partial cross-sectional view illustrating a backlight assembly according to another exemplary embodiment of the present invention;

FIG. 7 is a plan view illustrating an exemplary embodiment of an insulation layer of the backlight assembly illustrated in FIG. 6;

FIG. 8 is a partial cross-sectional view illustrating a backlight assembly according to still another exemplary embodiment of the present invention;

FIG. 9 is an exploded perspective view illustrating a backlight assembly according to still another exemplary embodiment of the present invention;

FIG. 10 is cross-sectional view illustrating a backlight assembly according to still another exemplary embodiment of the present invention; and

FIG. 11 is an exploded perspective view illustrating a liquid crystal display device according to an exemplary embodiment of the present invention.

### DESCRIPTION OF THE EMBODIMENTS

The present invention will now be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. It will be understood that when an element is referred to as being “on” or “onto” another element, it may be directly on the other element or intervening elements may also be present. In contrast, when an element is referred to as being “directly on” another element, there are no intervening elements present. Like reference numerals refer to similar or identical elements throughout.

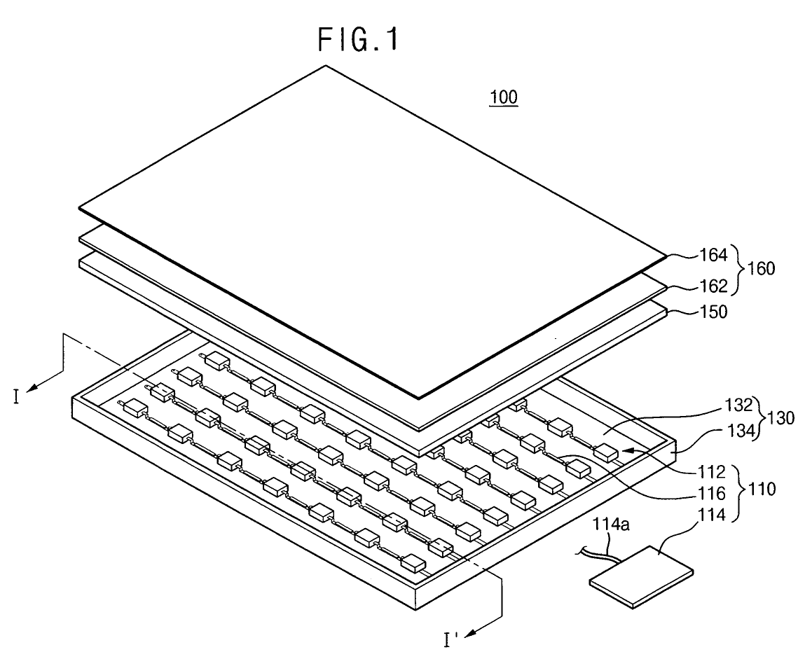

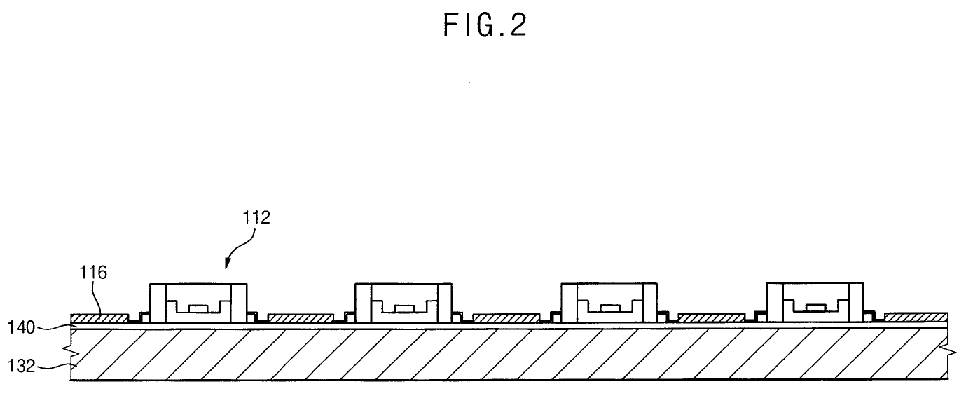

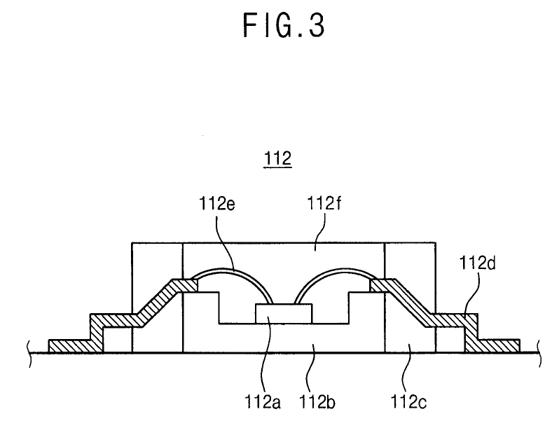

FIG. 1 is an exploded perspective view illustrating a backlight assembly according to an exemplary embodiment of the present invention. FIG. 2 is a partial cross-sectional view taken along a line I-I′ in FIG. 1. FIG. 3 is a cross-sectional view illustrating a point light source of the backlight assembly illustrated in FIG. 1.

Referring to FIGS. 1 and 2, a backlight assembly 100 includes a light-generating unit 110 and a receiving container 130.

The light-generating unit 110 includes a plurality of point light sources 112, a power supply unit 114 and a power supply line 116. The point light sources 112 have substantially the same structure and function. Thus, one point light source 112 will be described in detail.

Referring to FIG. 3, the point light source 112 is formed on a bottom plate 132 of the receiving container 130. In an exemplary embodiment, the point light source 112 includes a light emitting diode (LED) chip 112a, a heat sink 112b, a housing 112c, a lead 112d, a bonding wire 112e and a protective layer 112f.

The LED chip 112a generates light. For example, the LED chip 112a generates white light. Alternatively, the LED chip 112a may generate monochromatic light such as red light, blue light, green light.

The heat sink 112b is disposed under the LED chip 112a to externally transfer the heat generated from the LED chip 112a. Thus, the heat sink 112b has a low thermal resistance. The heat generated from the LED chip 112a is transferred to the receiving container 130 through the heat sink 112b.

The housing 112c serves as a body of the point light source 112. The housing 112c encloses the LED chip 112a and the heat sink 112b.

The lead 112d extends the outside of the housing 112c, and the lead 112d is electrically connected to the power supply line 116. The lead 112d applies a driving voltage provided from the power supply line 116 to the LED chip 112a. A pair of leads 112d is electrically connected to a positive electrode and a negative electrode of the LED chip 112a. The bonding wire 112e provides the driving voltage transmitted through the lead 112d to the LED chip 112a. The bonding wire 112e includes, for example, gold (Au).

The protective layer 112f is formed on the LED chip 112a and the heat sink 112b to fill in the housing 112c. The protective layer 112f includes, for example, a diffused epoxy resin. Thus, the protective layer 112f may isolate and protect the LED chip 112a from the exterior, and also diffuse the light emitted from the LED chip 112a.

In FIG. 3, the point light source 112 has the above-described structure. Alternatively, the point light source 112 may have various structures. For example, the point light source 112 may include a lens disposed over the LED chip 112a. Here, the lens may correspond to a top-emitting type having a dome shape. Alternatively, the lens may correspond to a side-emitting type.

Referring again to FIGS. 1 and 2, the power supply unit 114 generates a driving voltage for driving the point light sources 112. The driving voltage generated from the power supply unit 114 is applied to the point light sources 112 through the power supply wire 114a.

The power supply line 116 is formed on the receiving container 130, and transmits the driving voltage generated from the power supply unit 114 to the point light sources 112.

The receiving container 130 includes a bottom plate 132 and a sidewall 134. The receiving container 130 includes, for example, metal having great strength and low transformation.

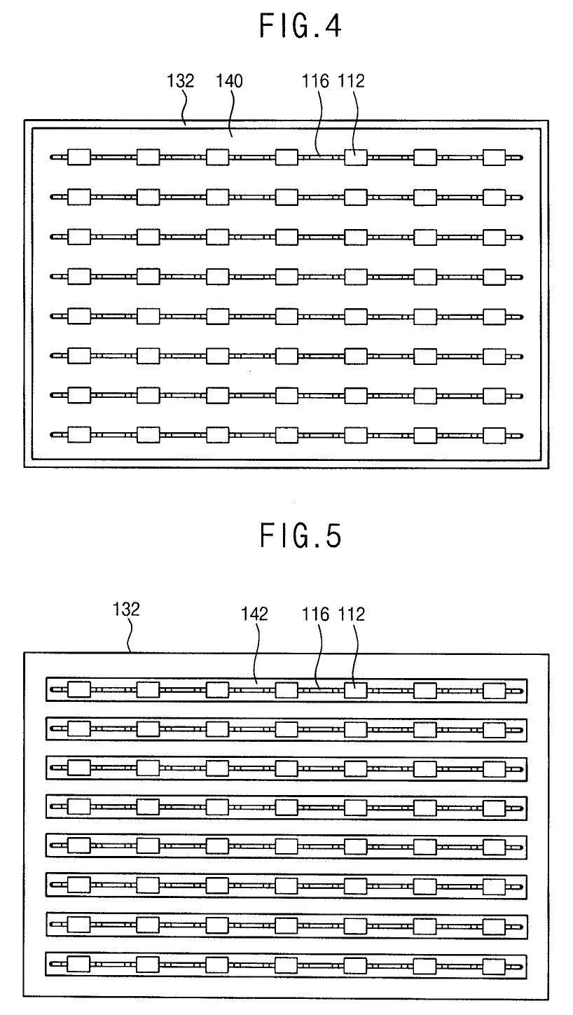

The bottom plate 132 has, for example, a substantially rectangular plate shape. The power supply line 116 of the light-generating unit 110 is formed on the bottom plate 132 of the receiving container 130. In an exemplary embodiment, the power supply line 116 includes a plurality of lines that is formed on the bottom plate 132 and substantially in parallel with a longitudinal direction of the receiving container 130. Here, each of the lines is broken by a predetermined interval so that the point light source 112 may be disposed between the lines (refer to FIGS. 4 and 5).

Since the power supply line 116 is formed on the bottom plate 132 of the receiving container 130, a printed circuit board for driving the point light source 112 may be omitted. Thus, the manufacturing cost of the backlight assembly 100 may be reduced. Also, heat generated from the point light source 112 is transferred directly to the bottom plate 132 of the receiving container 130 and not through the printed circuit board, cooling the point light source 112. Therefore, the cooling efficiency of the backlight assembly 100 may be enhanced.

The sidewall 134 protrudes from an end portion of the bottom plate 132. The bottom plate 132 and the sidewall 134 define a receiving space for receiving the light-generating unit 110.

The backlight assembly 100 may further include an insulation layer 140. The insulation layer 140 is disposed between the bottom plate 132 of the receiving container 130 and the power supply line 116 of the light-generating unit 110 to insulate the point light sources 112 from each other. The insulation layer 140 includes, for example, ceramic, insulating polymer, or similar insulating materials.

An adhesive member (not shown) may be formed between the insulation layer 140 and the light-generating unit 110 to fasten the light-generating unit 110 to the receiving container 130. For example, the adhesive member includes a material having heat transfer characteristics to transfer heat generated from the light-generating unit 110 to the receiving container 130.

FIG. 4 is a plan view illustrating an exemplary embodiment of an insulation layer of the backlight assembly illustrated in FIG. 1.

Referring to FIG. 4, the insulation layer 140 is formed on the substantially entire bottom plate 132 of the receiving container 130. The insulation layer 140 electrically insulates the point light sources 112 from each other, and electrically insulates a positive electrode and a negative electrode of each point light source 112 from each other. At least two of the point light sources 112 may be electrically connected to each other through the power supply line 116 formed on the insulation layer 140.

The backlight assembly 100 having the above-described structure may be manufactured as follows.

First, the receiving container 130 is formed. Then, the insulation layer 140 is formed on the bottom plate 132 of the receiving container 130, and a conductive pattern is formed on the insulation layer 140. The conductive pattern serves as the power supply line 116. The point light source 112 is mounted on the bottom plate 132 of the receiving container 130 having the conductive pattern to be electrically connected to the conductive pattern.

The insulation layer 140 may be formed, for example, by coating an insulating material. Alternatively, the insulation layer 140 may be formed by laminating an insulation foil.

The conductive pattern may be formed by a printing method. In this case, the conductive pattern may be formed by using a motor. For example, first, the receiving container 130 is transported by using a first motor. Then, a printer head is transported by using a second motor that has a resolution higher than that of the first motor. Thereafter, a conductive material is ejected from the printer head to form the conductive pattern.

FIG. 5 is a plan view illustrating another exemplary embodiment of an insulation layer of the backlight assembly illustrated in FIG. 1.

Referring to FIG. 5, an insulation layer 142 is formed in a predetermined pattern on the bottom plate 132 of the receiving container 130.

For example, the insulation layer 142 includes a plurality of lines that is substantially in parallel with a longitudinal direction of the receiving container 130.

The insulation layer 142 electrically insulates the point light sources 112 from each other, and electrically insulates a positive electrode and a negative electrode of each point light source 112 from each other. At least two of the point light sources 112 may be electrically connected to each other through the power supply line 116 formed on the insulation layer 142.

The backlight assembly 100 having the above-described structure may be manufactured as follows.

First, the receiving container 130 is formed. Then, the insulation layer 142 is formed on the bottom plate 132 of the receiving container 130, and a conductive pattern is formed on the insulation layer 142. The conductive pattern serves as the power supply line 116. The point light source 112 is mounted on the bottom plate 132 of the receiving container 130 having the conductive pattern to be electrically connected to the conductive pattern.

The insulation layer 142 may be formed, for example, by a printing method. Examples of the printing method include an ink jet printing method using a printer head, a roll printing method. Alternatively, the insulation layer 142 may be formed by a screening method, a thermal chemical vapor deposition (thermal CVD) method.

When the insulation layer 142 is formed by a printing method, the insulation layer 142 may be formed by using a motor. For example, first, the receiving container 130 is transported by using a first motor. Then, a printer head is transported by using a second motor that has a resolution higher than that of the first motor. Thereafter, an insulating material is ejected from the printer head to form the conductive pattern.

The conductive pattern is formed by substantially the same process as the conductive pattern illustrated in FIG. 4. Thus, any further description will be omitted.

The insulation layers 140 and 142 and the power supply line 116, which are illustrated in FIGS. 3 and 4, may have various shapes in accordance with arrangement shapes of the point light sources 112. When the point light sources 112 are arranged in a stripe shape as shown in FIG. 1, the insulation layers 140 and 142 and the power supply line 116 is regularly formed corresponding to the arrangement shape of the point light sources 112. Alternatively, the point light sources 112 may be arranged in a zigzag shape or may be irregularly arranged. In this case, the insulation layers 140 and 142 and the power supply line 116 may be formed in a zigzag shape or may be irregularly formed, corresponding to the arrangement shape of the point light sources 112.

Referring again to FIG. 1, the backlight assembly 100 may further include a light guiding member 150.

The light guiding member 150 is disposed over the point light source 110, and spaced apart from the point light sources 110. The light guiding member 150 mixes the light generated from the point light sources 110, and the mixed light exits the light guiding member 150. For example, when the point light source 110 includes red, green and blue LEDs, the light guiding member 150 mixes red, green and blue lights emitted from the LEDs to generate substantially white light. The light guiding member 150 includes, for example, polymethyl methacrylate (PMMA).

The backlight assembly 100 may further include an optical member 160 disposed over the light guiding member 150.

In an exemplary embodiment, the optical member 160 includes a light-diffusing plate 162 and an optical sheet 164.

The light-diffusing plate 162 diffuses the light provided from the light guiding member 150 and improves luminance uniformity of the light. For example, the light-diffusing plate 150 has a plate shape having a predetermined thickness, and includes PMMA.

The optical sheet 164 improves optical characteristics of the diffused light from the light-diffusing plate 162. The optical sheet 164 includes, for example, a light-diffusing sheet that diffuses the diffused light once more and/or a light-condensing sheet that condenses the diffused light to a front direction to improve front view luminance of the diffused light.

According to the above-described backlight assembly 100, the power supply line 116 is formed on the receiving container 130, and thus a conventional printed circuit board disposed between the point light source 112 and the receiving container 130 may be omitted. Thus, a separate printed circuit board driving the point light source 112 is omitted, and the point light source 112 is mounted on the receiving container 130 to be driven, thereby reducing the manufacturing cost of the backlight assembly 100 having the point light source 112. Also, heat generated from the point light source 112 is transferred directly to the receiving container 130, and not through the printed circuit board. Thus, the cooling efficiency of the backlight assembly 100 may be enhanced. In addition, the thickness of the backlight assembly 100 may be reduced by the thickness of a printed circuit board for driving the point light source 112.

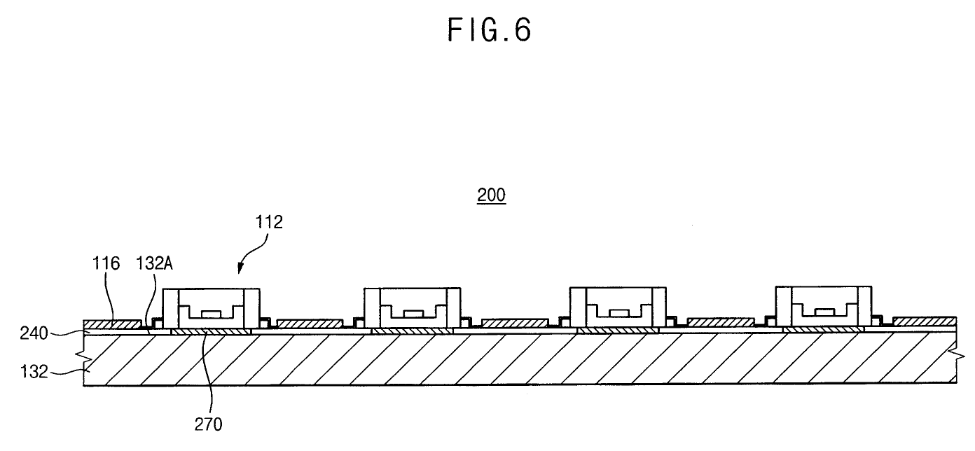

FIG. 6 is a partial cross-sectional view illustrating a backlight assembly according to another exemplary embodiment of the present invention.

Referring to FIG. 6, a backlight assembly 200 includes a light-generating unit, a receiving container, an insulation layer 240 and a heat transfer member 270.

The backlight assembly 200 is substantially the same as the backlight assembly 100 illustrated in FIG. 1 except for the insulation layer 240 and the heat transfer member 270. Thus, any further description concerning substantially the same parts will be omitted.

The insulation layer 240 is disposed between the exposed interior surface 132A of bottom plate 132 of the receiving container and the power supply line 116 of the light-generating unit. The insulation layer 240 electrically insulates the point light sources 112 from each other, and electrically insulates a positive electrode and a negative electrode of each point light source 112 from each other. The insulation layer 240 includes, for example, ceramic, insulating polymer, or similar insulating materials.

The heat transfer member 270 is positioned between the point light source 112 and surface 132 A of bottom plate 132 of the receiving container to transfer heat generated from the point light source 112 to the bottom plate 132. As shown in FIG. 6, a portion of the insulation layer 240 corresponding to the point light source 112 is removed, and the heat transfer member 270 is formed at the removed portion.

The heat transfer member 270 includes, for example, one of a thermally conductive adhesive and a solder material. Thus, the heat transfer member 270 may fasten the point light source 112 to the bottom plate 132 of the receiving container.

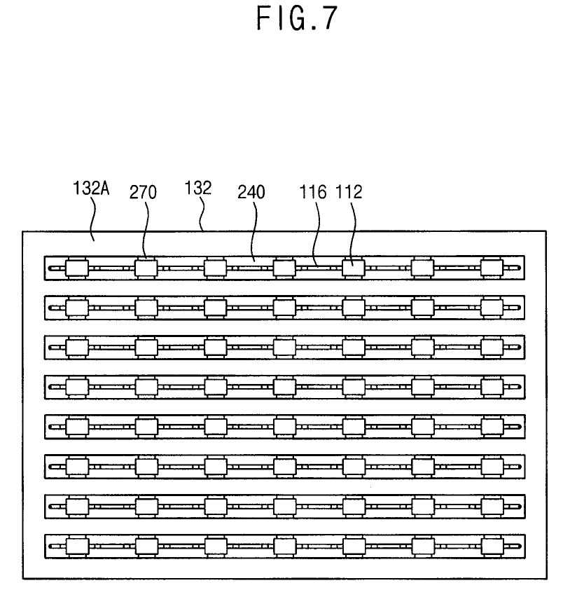

FIG. 7 is a plan view illustrating an exemplary embodiment of an insulation layer of the backlight assembly illustrated in FIG. 6.

Referring to FIG. 7, an insulation layer 240 is formed in a predetermined pattern on surface 132 A of bottom plate 132 of the receiving container.

For example, the insulation layer 240 includes a plurality of lines that is substantially in parallel with a longitudinal direction of the bottom plate 132 of the receiving container.

The insulation layer 240 electrically insulates the point light sources 112 from each other, and electrically insulates a positive electrode and a negative electrode of each point light source 112 from each other. At least two of the point light sources 112 may be electrically connected to each other through the power supply line 116 formed on the insulation layer 240.

Although the insulation layer 240 is formed in a pattern similar to the insulation layer 142 illustrated in FIG. 5 on the bottom plate 132 of the receiving container, each of the lines is broken corresponding to the point light source 112 by a predetermined interval.

The heat transfer member 270 is disposed at a space corresponding to the broken interval. The heat transfer member 270 is positioned between the point light source 112 and surface 132A of the receiving container to externally transfer the heat generated from the point light source 112.

The backlight assembly 200 having the above-described structure is manufactured by substantially the same method of manufacturing the backlight assembly 100 illustrated in FIG. 5. Thus, any further description will be omitted.

In FIG. 7, the insulation layer 240 includes a plurality of lines that is substantially in parallel with a longitudinal direction of the bottom plate 132 of the receiving container. Alternatively, the insulation layer 240 may be formed on an entire portion except for a portion on which the heat transfer member 270 is positioned. In this case, the insulation layer 240 may be formed by coating an insulating material, using a mask.

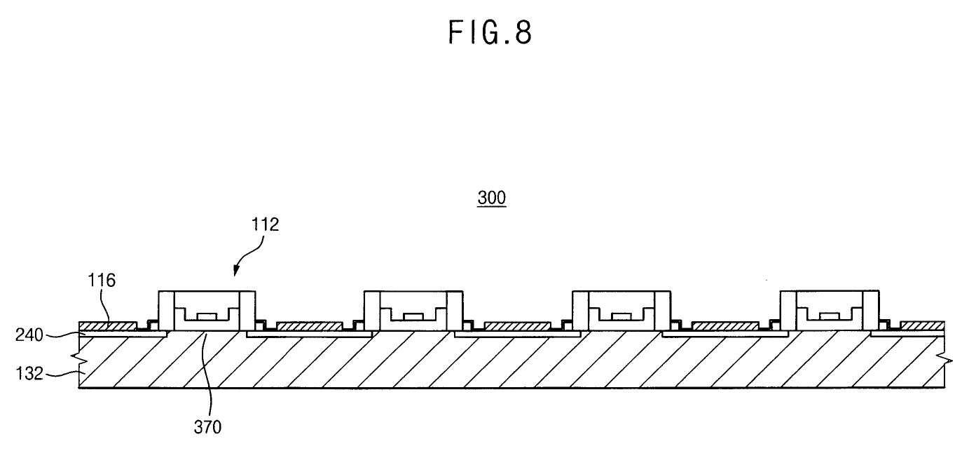

FIG. 8 is a partial cross-sectional view illustrating a backlight assembly according to still another exemplary embodiment of the present invention.

Referring to FIG. 8, a backlight assembly 300 includes a light-generating unit, a receiving container, an insulation layer 240 and a heat transfer member 370.

The backlight assembly 200 is substantially the same as the backlight assembly 200 illustrated in FIG. 6 except for the heat transfer member 370. Thus, any further description concerning substantially the same parts will be omitted.

The heat transfer member 370 is positioned between the point light source 112 and the bottom plate 132 of the receiving container to transfer the heat generated from the point light source 112 to the bottom plate 132. As shown in FIG. 8, a portion of the insulation layer 240 corresponding to the point light source 112 is removed, and the heat transfer member 370 is formed at the removed portion.

The heat transfer member 370 is integrally formed with the bottom plate 132, and protrudes from the upper surface of bottom plate 132. A protrusive length of the heat transfer member 370 from the bottom plate 132 is, for example, substantially the same as a thickness of the insulation layer 240.

An adhesive member (not shown) may be formed between the heat transfer member 370 and the point light source 112 to adhere the point light source 112 to the heat transfer member 370. Thus, the adhesive member may fasten the point light source 112 to the bottom plate 132 of the receiving container. For example, the adhesive member includes a material having heat transfer characteristics to transfer the heat generated from the light-generating unit 110 to the heat transfer member 370.

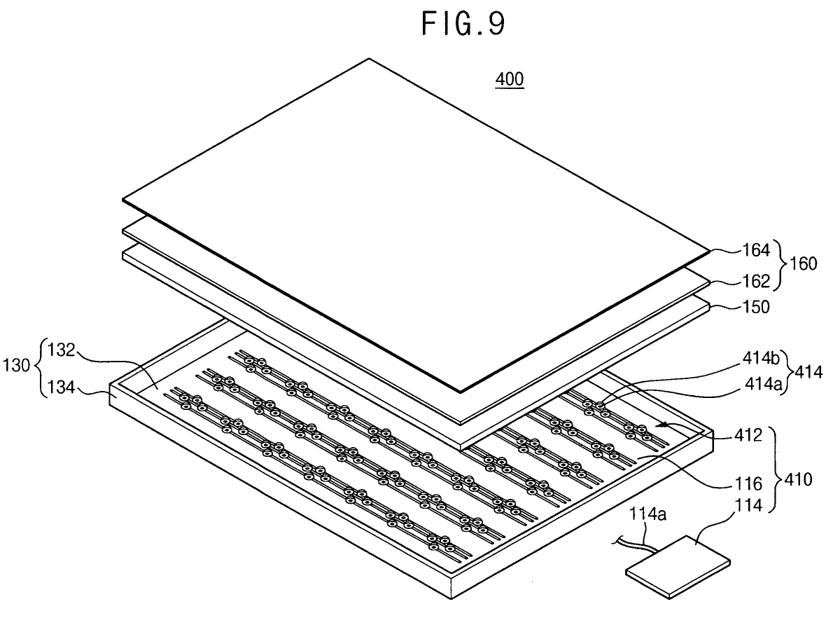

FIG. 9 is an exploded perspective view illustrating a backlight assembly according to still another exemplary embodiment of the present invention.

Referring to FIG. 9, a backlight assembly 400 includes a light-generating unit 410, a receiving container 130 and an insulation layer 140. The backlight assembly 400 may further include a light guiding member 150 and an optical member 160.

The backlight assembly 400 is substantially the same as the backlight assembly 100 illustrated in FIG. 1 except for the light-generating unit 410. Thus, any further description concerning substantially the same parts will be omitted.

The light-generating unit 410 includes a plurality of light source groups 412, a power supply unit 114 and a power supply line 116.

Each of the light source groups 412 includes a plurality of point light sources 414, and the light source groups 412 are spaced apart from each other. Each of the point light sources 414 may include an LED generating monochromatic light. For example, the point light sources 414 include red, green and blue LEDs.

In an exemplary embodiment, as shown in FIG. 9, each light source group 412 includes one red point light source, two green point light sources and one blue point light source. However, each number of red point light sources, green point light sources and blue point light sources is not limited to the above-described number.

Each of the point light sources 414 may include an LED chip 414a and a lens 414b disposed over the LED chip 414a. The lens 414b, as shown in FIG. 9, may correspond to a top-emitting type having a dome shape. Alternatively, the lens 414b may correspond to a side-emitting type. Alternatively, the point light sources 414 may be substantially the same as the point light source 112 illustrated in FIG. 1.

The power supply unit 114 and the power supply line 116 are substantially the same as the power supply unit 114 and the power supply line 116 illustrated in FIG. 1, respectively. Thus, any further description will be omitted.

In FIG. 9, the light-generating unit 410 is employed in the backlight assembly 100 illustrated in FIG. 1. Alternatively, the light-generating unit 410 may be employed in the backlight assemblies 200 and 300 illustrated FIGS. 6 and 8, respectively.

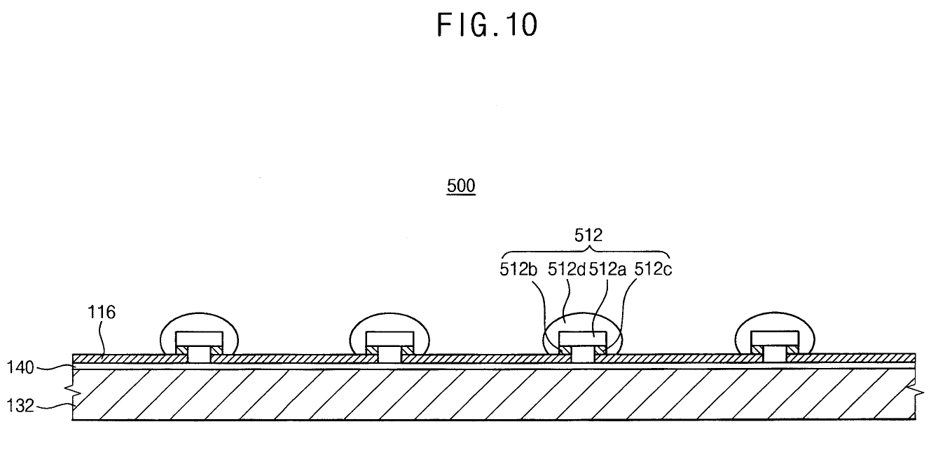

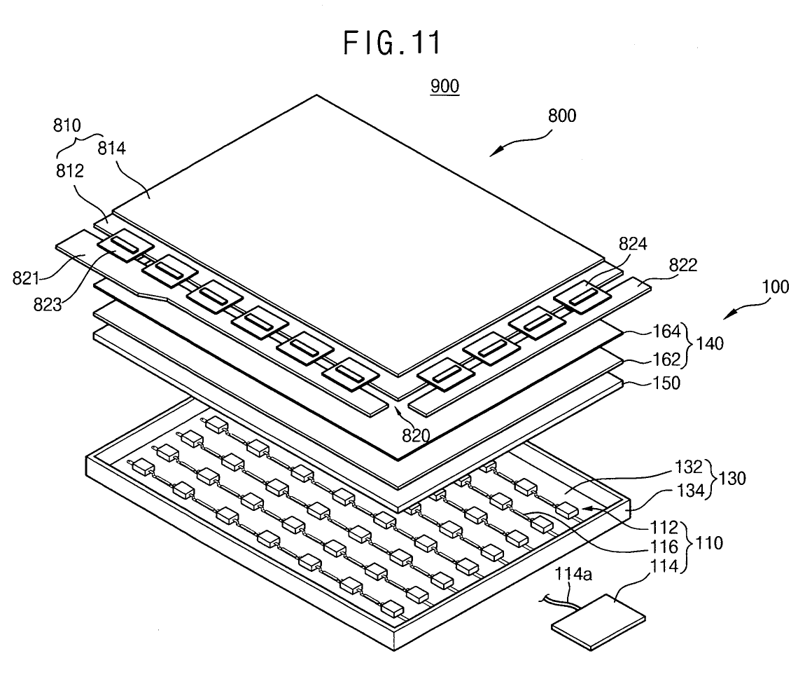

FIG. 10 is an exploded perspective view illustrating a backlight assembly according to still another exemplary embodiment of the present invention.

Referring to FIG. 10, a backlight assembly 500 includes a light-generating unit, a receiving container and an insulation layer 140. The backlight assembly 500 may further include a light guiding member and an optical member.

The backlight assembly 500 is substantially the same as the backlight assembly 100 illustrated in FIG. 1 except for a point light source 512 of the light-generating unit. Thus, any further description concerning substantially the same parts will be omitted.

The light-generating unit includes a point light source 512, a power supply unit (not shown) and a power supply line 116.

The point light source 512 of the light-generating unit includes an LED chip 512a, a first electrode 512b, a second electrode 512c and an encapsulation layer 512d.

The LED chip 512a generates light. For example, the LED chip 512a generates white light. Alternatively, the LED chip 512a may generate monochromatic light such as red light, blue light, green light.

The first and second electrodes 512b and 512c are electrically connected to the power supply line 116. The first and second electrodes 512b and 512c apply a driving voltage provided from the power supply line 116 to the LED chip 512a. For example, the first and second electrodes 512b and 512c serve as a positive electrode and a negative electrode of the LED chip 512a, respectively.

The encapsulation layer 512d covers the LED chip 512a. The encapsulation layer 512d includes, for example, epoxy resin, or silicon. The encapsulation layer 512d may isolate and protect the LED chip 512a from the exterior, and also diffuse the light emitted from the LED chip 512a.

The point light source 512 of the light-generating unit may correspond to a flip chip type. For example, the point light source 512 does not have a package form, and the LED chip 512a is directly mounted on the bottom plate 132 of the receiving container, thereby miniaturizing and lightening the backlight assembly 500, and increasing a signal transmission speed in comparison with the backlight assembly having additional elements such as a lead.

For example, the LED chip 512a is placed to be electrically connected to the power supply line 116 and then is encapsulated to thereby form the point light source 512.

In FIG. 10, the light-generating unit is employed in the backlight assembly 100 illustrated in FIG. 1. Alternatively, the light-generating unit 410 may be employed in the backlight assemblies 200, 300 and 400 illustrated FIGS. 6, 8 and 9, respectively.

FIG. 11 is an exploded perspective view illustrating a liquid crystal display device according to an exemplary embodiment of the present invention.

Referring to FIG. 11, a liquid crystal display (LCD) device 900 includes a backlight assembly 100 and a display unit 800.

The backlight assembly 100 is substantially the same as the backlight assembly 100 illustrated in FIG. 1. Thus, any further description concerning substantially the same parts will be omitted.

The display unit 800 includes an LCD panel 810 displaying an image using light provided from the backlight assembly 100 and a driver circuit part 820 driving the LCD panel 810.

The LCD panel 810 includes a first substrate 812, a second substrate 814 facing and coupled to the first substrate 812, and a liquid crystal layer (not shown) interposed between the first substrate 812 and the second substrate 814.

For example, the first substrate 812 includes a thin film transistor (TFT) serving as a switching element and a pixel electrode (not shown) electrically connected to the TFT.

For example, the second substrate 814 includes a common electrode (not shown) and a color filter layer (not shown).

The driver circuit part 820 includes a data printed circuit board 821 providing a data driving signal to the LCD panel 810, a gate printed circuit board 822 providing a gate driving signal to the LCD panel 810, a data driving circuit film 823 electrically connecting the data printed circuit board 821 to the LCD panel 810 and a gate driving circuit film 824 electrically connecting the gate printed circuit board 822 to the LCD panel 810.

In FIG. 11, the LCD device 900 employs the backlight assembly 100 illustrated in FIG. 1. Alternatively, the LCD device 900 may employ one of the backlight assemblies 200, 300, 400 and 500 illustrated in FIGS. 6, 8, 9 and 10, respectively.

According to the present invention, a power supply line transferring a power source for driving a point light source is formed on a receiving container, and thus a conventional printed circuit board disposed between the point light source and the receiving container may be omitted.

Thus, a separate printed circuit board driving the point light source is omitted, and the point light source is mounted on the receiving container to be driven, thereby reducing manufacturing cost of the backlight assembly having the point light source.

Also, heat generated from the point light source is transferred directly to the receiving container, and not through the printed circuit board. Thus, cooling efficiency of the backlight assembly may be enhanced.

In addition, the thickness of the backlight assembly may be reduced by the thickness of a printed circuit board for driving the point light source.

Although exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A backlight assembly comprising:
a light-generating unit comprising at least one point light source configured to generate light;
a receiving container configured to receive the light-generating unit;
an insulating layer formed on the receiving container; and
a power supply line formed on the insulating layer to transfer power to the at least one point light source.

2. The backlight assembly of claim 1, wherein the receiving container comprises a bottom plate and a sidewall protruding from an edge portion of the bottom plate to define a receiving space; and the insulating layer is positioned on an exposed interior surface at the bottom plate.

3. The backlight assembly of claim 2, wherein the light-generating unit comprises a plurality of point light sources, and further wherein the backlight assembly includes a plurality of power supply lines formed on the insulating layer and are connected to the point light sources.

4. The backlight assembly of claim 3, further comprising a plurality of heat transfer members each corresponding to an associated point light source, the heat transfer members being disposed between the associated point light source and the exposed interior surface of the bottom plate of the receiving container.

5. The backlight assembly of claim 4, wherein the heat transfer members fasten the point light sources to the exposed interior surface of the bottom plate of the receiving container.

6. The backlight assembly of claim 4, wherein the heat transfer members comprise one of a thermally conductive adhesive and a solder material.

7. The backlight assembly of claim 4, wherein the heat transfer members are integrally formed with the bottom plate of the receiving container, and the heat transfer members protrude from the exposed interior surface of the bottom plate.

8. The backlight assembly of claim 7, further comprising an adhesive member disposed between the heat transfer member and the point light source to adhere the heat transfer member to the point light source.

9. The backlight assembly of claim 1, wherein the point light source comprises:
a light emitting diode (LED) chip configured to generate light;
a first electrode and a second electrode that are electrically connected to the power supply line to apply a power source to the LED chip; and
an encapsulation layer configured to cover and encapsulate the LED chip.

10. A backlight assembly comprising:
a light-generating unit comprising at least one point light source configured to generate light; and
a receiving container comprising a bottom plate and a sidewall and receiving the light-generating unit in a receiving space defined by the bottom plate and the sidewall, the point light source of the light-generating unit being formed on the bottom plate of the receiving container.

11. The backlight assembly of claim 10, further comprising an electrically insulating material positioned on an exposed interior surface of the bottom plate, wherein the light-generating unit further comprises a power supply line configured to transfer a power to the point light source, and further wherein the power supply line is formed on the electrically insulating material.

12. The backlight assembly of claim 10, wherein the light-generating unit comprises a plurality of point light sources, and an electrically insulating layer is positioned between the exposed interior surface of the bottom plate and the power supply line of the light-generating unit to electrically insulate the point light sources from each other.

13. The backlight assembly of claim 10, further comprising a heat transfer member disposed between the point light source and the exposed interior surface of the bottom plate to fasten the point light source to the bottom plate of the receiving container.

14. A method of manufacturing a backlight assembly comprising:
forming a receiving container comprising a bottom plate and a sidewall define a receiving space;
forming an insulation layer on an exposed interior surface of the bottom plate;
forming a conductive pattern on the insulation layer; and
forming a point light source on the exposed interior surface of the bottom plate having the conductive pattern;
connecting the point light source to the conductive pattern

15. The method of claim 14, wherein the insulation layer is formed by one of coating an insulating material and laminating an insulation foil, and the insulation layer is formed on an entire portion of the bottom plate of the receiving container.

16. The method of claim 14, wherein at least one of the insulation layer and the conductive pattern is formed by a printing method.

17. The method of claim 16, wherein forming the insulation layer comprises:
transporting the receiving container using a first motor;
transporting a printer head using a second motor, a resolution of the second motor being higher than a resolution of the first motor; and
ejecting an insulating material from the printer head.

18. The method of claim 16, wherein forming the conductive pattern comprises:
transporting the receiving container using a first motor;
transporting the printer head using a second motor, a resolution of the second motor being higher than a resolution of the first motor; and
ejecting a conductive material from the printer head.

19. A display device comprising:
a display unit configured to display an image by using light; and
a backlight assembly configured to provide the light to the display unit, the backlight assembly comprising:
a light-generating unit comprising at least one point light source configured to generate light and a power supply line configured to transfer a power source for driving the point light source; and
a receiving container configured to receive the light-generating unit, the power supply line being formed on the receiving container.
